(19) United States
(12) Patent Application Publication
(10) Pub. No.: US 2007/0063325 A1
(43) Pub. Date: Mar. 22, 2007

(54) Chip package structure and bumping process

(76) Inventors: Chun-Hung Lin, Tainan County (TW); Geng-Shin Shen, Tainan County (TW)

Correspondence Address: J.C. Patents, Suite 250, 4 Venture, Irvine, CA, 92618, US

(21) Appl. No.: 11/361,646

(22) Filed: Feb. 24, 2006

Related U.S. Application Data
(62) Division of application No. 11/234,774, filed on Sep. 22, 2005.

(51) Int. Cl. H01L 21/00

(52) U.S. Cl. 257/678; 438/106

(57) ABSTRACT

A chip package structure including a first substrate, a second substrate, bumps and adhesive blocks is provided. The first substrate has first bonding pads. The second substrate is disposed above the first substrate and has second bonding pads. The bumps are respectively arranged on the first bonding pads or the second bonding pads, and the second substrate is electrically connected to the first substrate through the bumps. The adhesive material with B-stage property are respectively arranged between the first bonding pads and the second bonding pads and enclose each bump. The bumps can be stud bumps or plating bumps.

### BACKGROUND OF THE INVENTION

1. Field of the Invention

The present invention generally relates to a chip package structure and a bumping process. More particularly, the present invention relates to a chip package structure and a bumping precess by using a bump and an adhesive material enclosing the bump, to electrically connect two substrates.

2. Description of Related Art

Following the increase of input/output contacts of an integrated circuit, chip package technology has become more and more diversified. This is due to the fact that Flip Chip (FC) Interconnect technology minimizes the size of the chip package, and reduces signal transmission path, etc. The most common used chip package structures applying the flip chip interconnect technology comprise the chip package structures, such as the Flip Chip Ball Grid Array (FC/BGA) and the Flip Chip Pin Grid Array (FC/PGA).

Flip chip interconnect technology employs the method of defining area array by disposing a plurality of bonding pads onto the active surface of the chip and forming a plurality of bumps on the bonding pads, respectively. Next, the chip is flipped to connect the bonding bumps of the chip and a plurality of contact pads disposed on a carrier such as a circuit substrate respectively. Therefore, the chip is electrically and mechanically connected to the carrier through the bumps. Further, the chip can be electrically connected to external electronic devices via the internal circuits of the carrier. Generally speaking, the bumps has several types such as the solder bump, the gold bump, the copper bump, the conductive polymer bump, the polymer bump, etc.

FIG. 1 is a schematic cross-sectional view showing a flip chip package structure having polymer bumps. Please refer to FIG. 1, the flip chip package structure 100 comprises a first substrate 110, a plurality of polymer bumps 120, a chip 130 and solder 140. The first substrate 110 has a surface 110a, and a plurality of contact pads 112 is disposed on the surface 110a. The chip 130 has an active surface 130a, and a plurality of bonding pads 132 is disposed on the active surface 130a. The polymer bumps 120 made of polymer material with conductive property are respectively arranged between the contact pads 112 and the bonding pads 132 for electrically connecting the substrate 110 and the chip 130. The polymer bumps 120 are not adhered to the contact pads 112, therefore, solder 140 is required for fixing the polymer bumps 120 on the substrate 110. The solder 140 is adhered to the contact pad 112 on the surface A and adhered to the polymer bump 120 on the surface B. Therefore, when external force or thermal stress (not shown) is applied to the flip chip package structure, the solder 140 may separate from the contact pads 112, and further the polymer bumps 120 would not be electrically connected to the contact pads 112. Thus, the reliability of the flip chip package structure is lower.

### SUMMARY OF THE INVENTION

A main purpose of the present invention is to provide a chip package structure, utilizing a plurality of bumps for electrically connecting a chip and a substrate. An adhesive material with B-stage property is adapted for enclosing the bumps, therefore, the reliability of the chip package structure is enhanced.

A second purpose of the present invention is to provide a bumping process. A plurality of bumps are formed on a surface of a substrate first, and then a plurality of adhesive material with B-stage property are formed to enclose the bumps respectively, in order to ensure the electrical connection between the substrate and the other substrate.

As embodied and broadly described herein, the present invention provides a chip package structure comprising a first substrate, a second substrate, a plurality of bumps and an adhesive material. The first substrate has first bonding pads. The second substrate is disposed above the first substrate and has second bonding pads. The bumps are respectively arranged on the first bonding pads or the second bonding pads, and the second substrate is electrically connected to the first substrate through the bumps. The adhesive material with B-stage property is arranged between the first bonding pads and the second bonding pads and enclosing each bump.

According to an embodiment of the present invention, the bumps comprise stud bumps or plating bumps.

According to an embodiment of the present invention, the adhesive material is an adhesive layer and the adhesive layer is non-conductive.

According to an embodiment of the present invention, the adhesive material comprises a plurality of adhesive blocks, and they can be conductive or non-conductive.

According to an embodiment of the present invention, the first substrate and the second substrate can be both chips.

According to an embodiment of the present invention, the first substrate can be a carrier and the second substrate can be a chip.

According to an embodiment of the present invention, the glass transition temperature of the adhesive blocks with B-stage property is between −40° C. and 175° C.

According to an embodiment of the present invention, the chip package structure further comprises a carrier and a plurality of bonding wires. The first substrate and the second substrate are disposed on the carrier, and the first substrate is electrically connected to the carrier through the bonding wires.

As embodied and broadly described herein, the present invention provides a bumping process, comprising: providing a substrate having a plurality of bonding pads; forming a bump on each bonding pad; forming a thermosetting adhesive material with two-stage property on the substrate, to enclose each bump; pre-curing the thermosetting adhesive material with two-stage property to form an adhesive material with B-stage property.

According to an embodiment of the present invention, the bumps comprise stud bumps or plating bumps.

According to an embodiment of the present invention, thermosetting adhesive material with two-stage property is formed by screen printing, painting, spraying, spinning or dipping.

According to an embodiment of the present invention, the thermosetting adhesive material is a thermosetting adhesive layer.

According to an embodiment of the present invention, the thermosetting adhesive material comprises a plurality of thermosetting adhesive blocks.

According to an embodiment of the present invention, the thermosetting adhesive material with two-stage property is pre-cured by being exposed to UV light.

According to an embodiment of the present invention, the thermosetting adhesive material with two-stage property is pre-cured by being heated.

According to an embodiment of the present invention, the glass transition temperature of the adhesive material with B-stage property is between −40° C. and 175° C.

In summary, the chip package structure of the present invention utilizes an adhesive material with B-stage property to enclose the bump. The substrate is electrically connected to the other one through the bumps, or through the bumps and the adhesive material enclosing them. The upper end and the lower end of the adhesive material are adhered to the bonding pads of the upper and the lower substrates respectively. Therefore, when an external force or thermal stress is applied to the chip package structure, the adhesive material enclosing the bumps is adapted for ensuring the electrical connection between the upper and the lower substrates, and further the reliability of the chip package structure is enhanced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view showing a flip chip package structure having polymer bumps.

FIG. 2 is a schematic cross-sectional view showing a chip package structure according to a first embodiment of the present invention.

FIG. 3 is a schematic cross-sectional view showing a chip package structure according to a second embodiment of the present invention.

FIG. 4 is a schematic cross-sectional view showing a stacked-type chip package structure according to one embodiment of the present invention.

FIGS. 5A to 5D are schematic, cross-sectional views illustrating a bumping process according to the present invention.

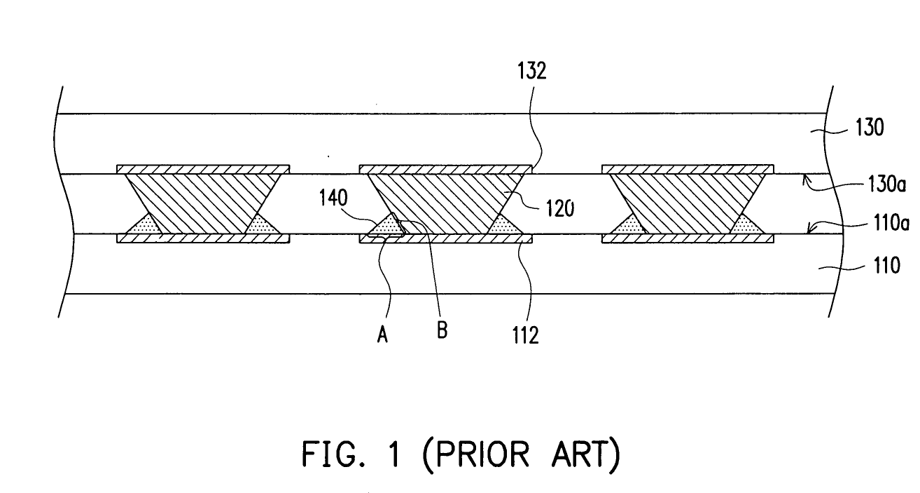

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

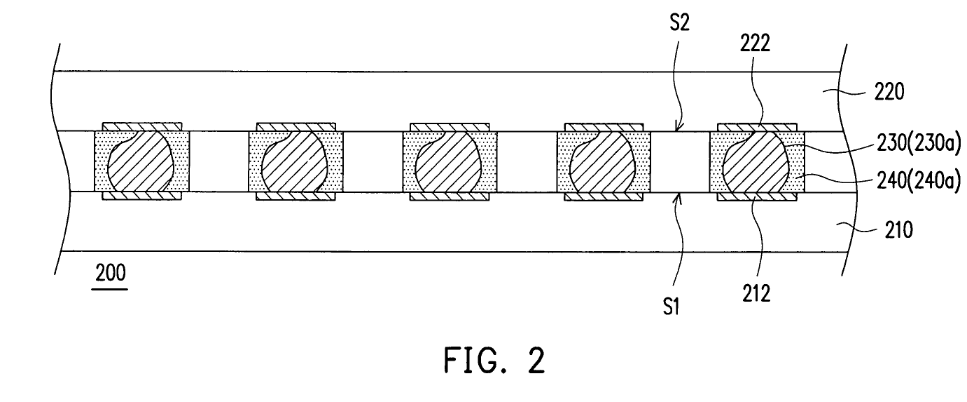

FIG. 2 is a schematic cross-sectional view showing a chip package structure according to a first embodiment of the present invention. Please refer to FIG. 2, the chip package structure 200 of the present invention mainly comprises a first substrate 210, a second substrate 220, a plurality of bumps 230 and an adhesive material 240 with B-stage property. The invention utilizes the bumps 230 for electrically connecting the first substrate 210 and the second substrate 220. Further, the adhesive material 240 with B-stage property enclosing the bumps 230 is adapted for increasing the adhesion between the first substrate 210 and the second substrate 220, to enhance the reliability of the chip package structure 200.

The first substrate 210 comprises a plurality of first bonding pads 212 arranged on a surface S1 thereof. The second substrate 220 is arranged above the first substrate 210 and also comprises a plurality of second bonding pads 222 arranged on a surface S2 thereof. According to one embodiment of the present invention, the first substrate 210 and the second substrate 220 can be both chips. Besides, the first substrate 210 can be a carrier, such as the printed circuit board (PCB), and the second substrate 220 can be a chip. The types of the first substrate 210 and the second substrate 220 are not limited in the present invention. The bumps 230 are respectively arranged on the first bonding pads 212 or the second bonding pads 222, and the upper end of each bump 230 contacts with the second bonding pad 222 and the lower end thereof contacts with the first bonding pads 212. In this embodiment, the bumps 230 are stud bumps 230a, and the stud bumps 230a can be gold stud bumps. Therefore, the second substrate 220 is electrically connected to the first substrate 210 through the stud bumps 230a.

The adhesive material 240 with B-stage property is arranged between the first bonding pads 212 and the second bonding pads 222. In this embodiment, the adhesive material 240 are a plurality of adhesive blocks 240a. Each adhesive blocks 240a encloses one of the bumps 230, and the upper end and the lower end of the adhesive blocks 240a are adhered to the second bonding pads 222 and the first bonding pads 212 respectively. Therefore, when an external force is applied to the chip package structure 200, the adhesive material 240 enclosing the bumps 230 are adapted for ensuring the electrical connection between the first substrate 210 and the second substrate 220, and further the reliability of the chip package structure 200 is enhanced. According to this embodiment, the adhesive blocks 240a can be conductive or non-conductive. If the adhesive blocks 240a are conductive, the second substrate 220 can also be electrically connected to the first substrate 210 through the adhesive blocks 240a. Furthermore, the glass transition temperature of the adhesive material 240 with B-stage property is between −40° C. and 175° C.

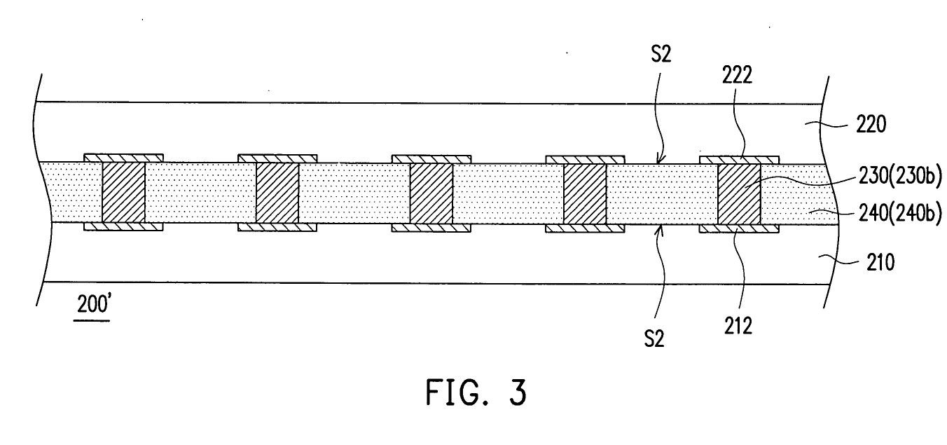

FIG. 3 is a schematic cross-sectional view showing a chip package structure according to a second embodiment of the present invention. Please refer to FIG. 3, the chip package structure 200′ is similar to the chip package structure 200 shown in FIG. 2. But the difference between them is that the bumps 230 are plating bumps 230b and the adhesive material 240 is an adhesive layer 240b with non-conductive property in the second embodiment. The material of the plating bumps 230b may comprise gold. Similarly, the adhesive layer 240b arranged between the first substrate 210 and the second substrate 220 is adapted for ensuring the electrical connection between the first substrate 210 and the second substrate 220. Therefore, the reliability of the chip package structure 200′ can be improved.

However, the stud bumps 230a of the first embodiment may apply to the second embodiment to replace the plating bumps 230b. Similarly, the adhesive layer 240b of the second embodiment, which is non-conductive, may apply to the first embodiment to replace the adhesive blocks 240a.

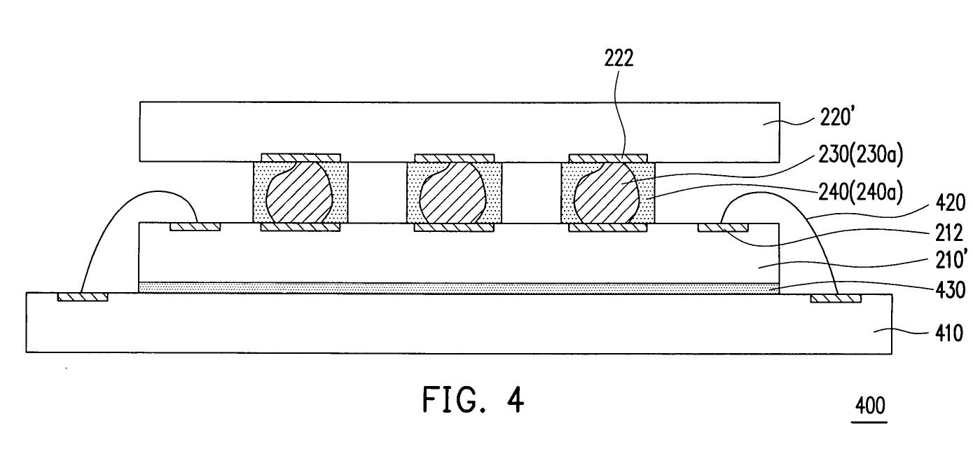

The structures shown in FIGS. 2 and 3 can be applied to a stacked-type chip package structure. FIG. 4 is a schematic cross-sectional view showing a stacked-type chip package structure according to one embodiment of the present invention. Please refer to FIG. 4, the stacked-type chip package structure 400 mainly comprises a carrier 410, a first chip 210′, a second chip 220′, a plurality of bumps 230, an adhesive material 240 and a plurality of bonding wires 420. The arrangement of the first chip 210′, the second chip 220′, the bumps 230 and the adhesive material 240 is the same as the first embodiment, and therefore it is not repeated herein. In this embodiment, the first chip 210′ is adhered to the carrier 410 through an adhesive layer 430, and is electrically connected to the carrier 410 via the bonding wires 420.

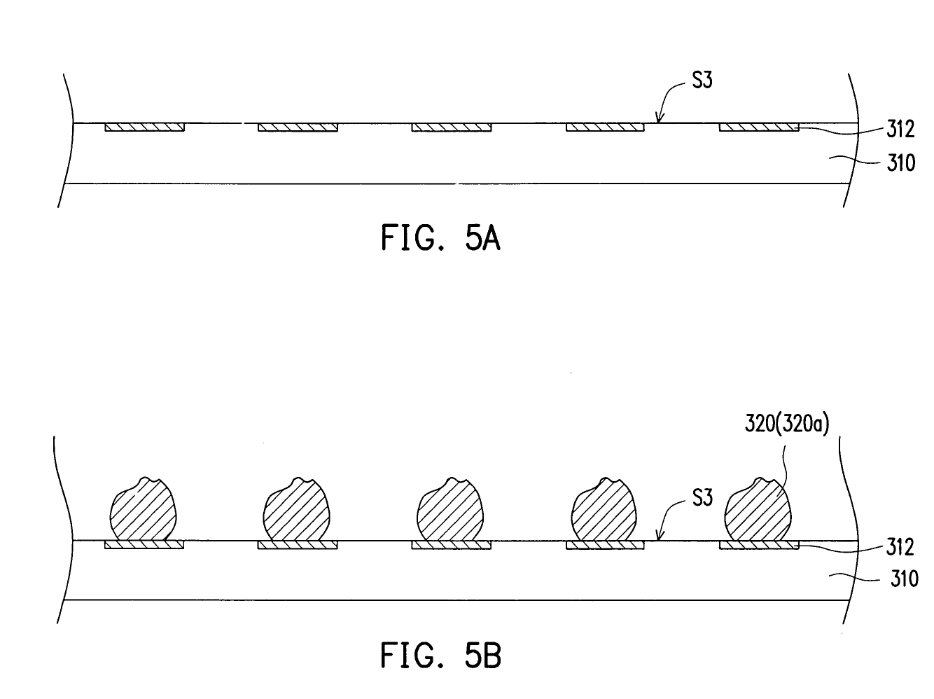

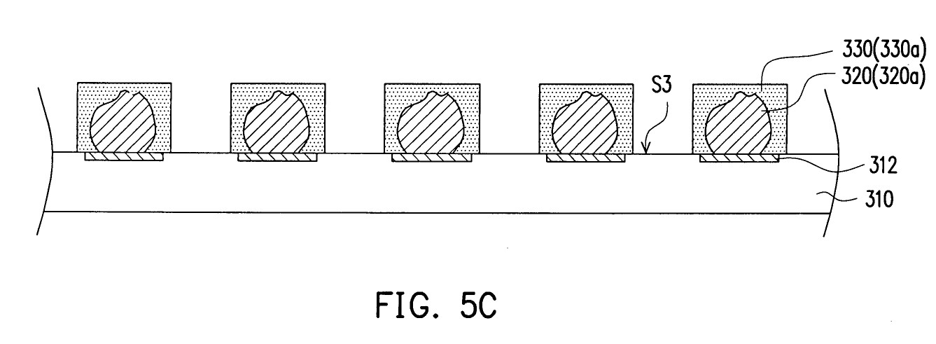

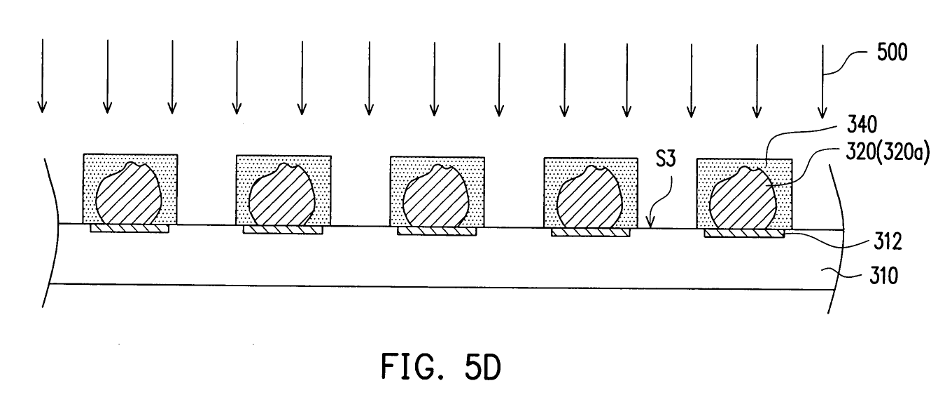

FIGS. 5A to 5D are schematic, cross-sectional views illustrating a bumping process according to the present invention. The bumping process described herein takes the above-mentioned first embodiment as an example for illustration. First, please refer to FIG. 5A, a substrate 310 having a plurality of bonding pads 312 is provided. The substrate 310 can be a carrier, such as a PCB, a chip and the like. The bonding pads 312 are arranged on a surface S3 of the substrate 310. Next, please refer to FIG. 5B, bumps 320 are formed on each bonding pad 312 and the material of the bumps 320 comprises gold. The substrate 310 can be electrically connected to other substrate (not shown) through the bump 320. In this embodiment, the bumps 320 are stud bumps 320a. Except the stud bumps 320a shown in FIG. 5B, the plating bumps 230b shown in FIG. 3 can be used to replace the stud bumps 320a, for electrically connecting the substrate 310 and other carrier.

After that, please refer to FIG. 5C, a thermosetting adhesive material 330 with two-stage (A-stage and B-stage) property are formed on the substrate 310, to enclose each bump 320. In this embodiment, the thermosetting adhesive material 330 comprises a plurality of thermosetting adhesive blocks 330a. The material of the thermosetting adhesive blocks 330a can be polyimide, polyquinolin, benzocyclobutene, and the like. Besides, the thermosetting adhesive blocks 330a can be conductive or non-conductive, and they can be formed not only by screen printing, but also by painting, spraying, spin-coating, or dipping. In this step, the thermosetting mixture is in liquid or gel state and so it is easy to spread on the surface S3 of the substrate 310. In another embodiment of the present invention, the thermosetting adhesive material 330 can also be an adhesive layer 240b shown in FIG. 3 with non-conductive property. Therefore, the type of the thermosetting adhesive material 330 is not limited in the present invention.

Finally, please refer to FIG. 5D, the thermosetting adhesive blocks 330a with two-stage property is pre-cured, to form a plurality of adhesive blocks 340 with B-stage property. Thus far, the bumping process of the present invention is completed. In this embodiment, the thermosetting adhesive blocks 330a with two-stage property is pre-cured by being exposed to UV light 500 or heated to form the adhesive blocks 340 with B-stage property. The glass transition temperature of the adhesive blocks 340 with B-stage property is between −40° C. and 175° C. Besides, the adhesive blocks 340 with B-stage property are non-adhesive and in a solid state at room temperature.

In summary, the chip package structure of the present invention utilizes an adhesive block with B-stage property to enclose the bump. The substrate is electrically connected to the other one through the bumps, or through the bumps and the adhesive material enclosing them. The upper end and the lower end of the adhesive material are adhered to the bonding pads of the upper and the lower substrates respectively. Therefore, when an external force or thermal stress is applied to the chip package structure, the adhesive material enclosing the bumps is adapted for ensuring the electrical connection between the upper and the lower substrates, and further the reliability of the chip package structure is enhanced.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

1-10. (canceled)

11. A bumping process, comprising:
providing a substrate having a plurality of bonding pads;
forming a bump on each bonding pad;
forming a thermosetting adhesive material with two-stage property on the substrate, to enclose each bump; and
pre-curing the thermosetting adhesive material with two-stage property to form an adhesive material with B-stage property.

12. The bumping process according to claim 11, wherein the bumps comprise stud bumps or plating bumps.

13. The bumping process according to claim 11, wherein the thermosetting adhesive material with two-stage property is formed by screen printing, painting, spraying, spinning or dipping.

14. The bumping process according to claim 11, wherein the thermosetting adhesive material is a thermosetting adhesive layer.

15. The bumping process according to claim 11, wherein the thermosetting adhesive material comprises a plurality of thermosetting adhesive blocks.

16. The bumping process according to claim 11, wherein the thermosetting adhesive material with two-stage property is pre-cured by being exposed to UV light.

17. The bumping process according to claim 11, wherein the thermosetting adhesive material with two-stage property is pre-cured by being heated.

18. The bumping process according to claim 11, wherein the glass transition temperature of the adhesive material with B-stage property is between −40° C. and 175° C.
